(19) United States
(12) Patent Application Publication
(10) Pub. No.: US 2025/0336639 A1
(43) Pub. Date: Oct. 30, 2025

(54) ENHANCED EDGE DETECTION USING DETECTOR INCIDENCE LOCATIONS

(71) Applicant: ASML NETHERLANDS B.V., Veldhoven (NL)

(72) Inventors: Ilse VAN WEPEREN, Veldhoven (NL); Maikel Robert GOOSEN, Eindhoven (NL)

(73) Assignee: ASML NETHERLANDS B.V., Veldhoven (NL)

(21) Appl. No.: 18/866,475

(22) PCT Filed: Jul. 11, 2023
(86) PCT No.: PCT/EP2023/069237

§ 371 Date: Nov. 15, 2024

(30) Foreign Application Priority Data
Jul. 21, 2022 (EP) 22186346.7

(51) Int. Cl. H01J 37/244; H01J 37/28

(52) U.S. Cl. CPC H01J 37/244; H01J 37/28; H01J 2237/2441; H01J 2237/24465; H01J 2237/24578; H01J 2237/24585; H01J 2237/24592; H01J 2237/2814; H01J 2237/2817

(57) ABSTRACT

A system and method for enhanced edge detection in charged particle beam systems such as scanning electron microscopes. The method uses spatial information of the incidence locations of charged particle arrival events on a detector surface to determine when an edge feature is being detected on a sample. An asymmetry parameter, such as shift in the center of mass of a distribution of charged particle arrival events, may be used to determine the presence of an edge feature on a sample surface.

### CROSS-REFERENCE TO RELATED APPLICATIONS

This application claims priority of EP application 22186346.7 which was filed on July 21, 2022 and which is incorporated herein in its entirety by reference.

### FIELD

The description herein relates to charged particle detectors that may be useful in the field of charged particle beam systems, and more particularly, to systems and methods for detecting an edge feature using such charged particle beam detectors.

### BACKGROUND

Detectors may be used for sensing physically observable phenomena. For example, charged particle beam tools, such as electron microscopes, may comprise detectors that receive charged particles projected from a sample and that output detection signals. Detection signals may be used to reconstruct images of sample structures under inspection and may be used, for example, in metrology processes or to reveal defects in the sample. Metrology relates to precision measurements of sample structures and other miniaturized features. For example, in a semiconductor wafer, metrology may include measurements of circuit pattern features such as critical dimension (width of the smallest device feature), critical dimension uniformity, linewidth, overlay, line edge roughness, line end shortening, floor tilt, sidewall angle, and other dimensional parameters. A key element in many measurements may involve determining the location of an edge, or boundary, of a pattern feature. These edge features may correspond to a change in topography or material properties of a pattern formed on the wafer. Detection of defects in a sample is also increasingly important in the manufacturing of semiconductor devices, which may include large numbers of densely packed, miniaturized integrated circuit (IC) components. Inspection systems may be provided for these and other purposes.

With continuing miniaturization of semiconductor devices, metrology and inspection systems may use lower and lower beam currents in charged particle beam tools. Existing detection systems may be limited by signal-to-noise ratio (SNR) and system throughput, particularly when beam current reduces to, for example, pico-ampere ranges. Electron counting has been proposed to enhance SNR and to increase throughput in electron beam inspection systems, wherein the intensity of an incoming electron beam is acquired by counting the number of electrons that reach the detector, and then analyzing the frequency of electron arrival events. However, systems operating at increasingly lower landing energies (the energy of a primary electron striking a sample surface) may require a higher electron collection rate to overcome noise in the system. This leads to increased integration time and lower tool throughput.

### SUMMARY

Embodiments of the present disclosure provide systems and methods for edge detection in a charged particle beam process. Some embodiments of the present disclosure provide a method comprising: inspecting a sample surface using a charged particle beam system; obtaining spatial distribution information of locations of detected charged particle arrivals on a charged particle detector; determining an asymmetry parameter of the spatial distribution information; and determining an edge feature on the sample surface based on the asymmetry parameter.

In some embodiments, the asymmetry parameter may comprise position parameter. The position parameter may comprise a deviation of a center of mass (COM) of the locations of detected charged particle arrivals, the deviation resulting from the edge feature.

Some embodiments of the present disclosure provide a method comprising: inspecting a sample surface using a charged particle beam system; obtaining first spatial distribution information of locations of detected charged particle arrivals on a charged particle detector in a first time period; obtaining second spatial distribution information of locations of detected charged particle arrivals on the charged particle detector in a second time period different from the first time period; determining a performance parameter of the charged particle beam system based on the first spatial distribution information and the second spatial distribution information; and performing an adjustment to the charged particle system based on the determined performance parameter.

Some embodiments of the present disclosure provide a charged particle beam method, comprising: inspecting a sample surface using a charged particle beam system; detecting a plurality of sample pixels within a field of view of the sample, wherein detecting each sample pixel of the plurality of sample pixels comprises detecting a plurality of charged particles emitted from the sample pixel; and determining a map of center of mass deviations of each plurality of charged particles emitted from each sample pixel of the plurality of sample pixels.

Some embodiments provide a non-transitory computer-readable medium storing a set of instructions that are executable by at least one processor of a device to cause the device to perform the above methods. Some embodiments provide a charged particle beam apparatus comprising a controller configured to control the apparatus to perform the above methods.

### BRIEF DESCRIPTION OF THE DRAWINGS

The above and other aspects of the present disclosure will become more apparent from the description of exemplary embodiments, taken in conjunction with the accompanying drawings.

FIG. 1 is a diagrammatic representation of an exemplary electron beam inspection (EBI) system, consistent with embodiments of the present disclosure.

FIGS. 2A-C are diagrams illustrating charged particle beam apparatus that may be examples of an electron beam tool, consistent with embodiments of the present disclosure.

FIG. 2D illustrates an electron arrival distribution on an exemplary detector in a charged particle beam apparatus, consistent with embodiments of the present disclosure.

FIGS. 3A-B are diagrammatic representations of exemplary structures of a detector in a charged particle beam apparatus, consistent with embodiments of the present disclosure.

FIGS. 4A-B illustrate example probability distributions of electron arrival locations on a detector surface, consistent with embodiments of the present disclosure.

FIG. 4C illustrates an example cross-sectional view of a line and space pattern on a portion of a wafer, consistent with embodiments of the present disclosure.

FIGS. 5A-B illustrate example electron arrival distributions on a detector surface, consistent with embodiments of the present disclosure.

FIG. 6A illustrates an example center of mass (COM) map, consistent with embodiments of the present disclosure.

FIG. 6B illustrates an example secondary electron yield map, consistent with embodiments of the present disclosure.

FIGS. 7A-B illustrate example electron arrival distributions on a detector surface, consistent with embodiments of the present disclosure.

FIG. 8 illustrates an example graph of COM deviation vs number of secondary electron arrivals, consistent with embodiments of the present disclosure.

FIG. 9 illustrates a flowchart of an example method of determining edge features in a charged particle beam detection process, consistent with embodiments of the present disclosure.

FIG. 10 illustrates a flowchart of an example method of determining edge features in a charged particle beam detection process, consistent with embodiments of the present disclosure.

### DETAILED DESCRIPTION

Reference will now be made in detail to exemplary embodiments, examples of which are illustrated in the drawings. The following description refers to the accompanying drawings in which the same numbers in different drawings represent the same or similar elements unless otherwise represented. The implementations set forth in the following description of exemplary embodiments do not represent all implementations consistent with the invention. Instead, they are merely examples of apparatuses, systems, and methods consistent with aspects related to subject matter that may be recited in the appended claims.

Electronic devices are constructed of circuits formed on a piece of silicon called a substrate. Many circuits may be formed together on the same piece of silicon and are called integrated circuits or ICs. With advancements in technology, the size of these circuits has decreased dramatically so that many more of them can fit on the substrate. For example, an IC chip in a smart phone can be as small as a fingernail and yet may include over 2 billion transistors, the size of each transistor being less than 1/1,000th the width of a human hair.

Making these extremely small ICs is a complex, time-consuming, and expensive process, often involving hundreds of individual steps. Errors in even one step have the potential to result in defects in the finished IC, rendering it useless. Thus, one goal of the manufacturing process is to avoid such defects to maximize the number of functional ICs made in the process, that is, to improve the overall yield of the process.

One component of improving yield is monitoring the chip making process to ensure that it is producing a sufficient number of functional integrated circuits. One way to monitor the process is to inspect the chip circuit structures at various stages of their formation. Inspection can be carried out using a scanning electron microscope (SEM). A SEM can be used to image these extremely small structures, in effect, taking a “picture” of the structures. The image can be used to determine if the structure was formed properly and also if it was formed in the proper location. If the structure is defective, then the process can be adjusted so the defect is less likely to recur. To enhance throughput (e.g., the number of samples processed per hour), it is desirable to conduct inspection as quickly as possible.

An image of a wafer may be formed by scanning one or more primary beams of a SEM system (e.g., a “probe” beam) over the wafer and collecting particles (e.g., secondary electrons, or “SEs”) generated from the wafer surface at a detector. Secondary electrons may form one or more secondary beams that are directed toward the detector. For each secondary beam, secondary electrons arriving at the detector may cause electrical signals (e.g., current, charge, voltage, etc.) to be generated in the detector. These signals may be output from the detector and may be processed by an image processor to form the image of the sample. Each pixel of the image may be determined by the energy received at the detector when a primary beam irradiates the corresponding point (sample pixel) on the sample surface.

Sometimes the detection process involves measuring the magnitude of an electrical signal generated when a large number of electrons land on the detector. In another approach, electron counting may be used, in which a detector may count individual electron arrival events as they occur. In either approach, intensity of the secondary beam may be determined based on electrical signals generated in the detector that vary in proportion to the change in intensity of the secondary beam. Using electron counting, however, each electron that reaches the detector from a beam of secondary electrons may be determined individually, and detection results may be output in digital form. Thus the intensity of the beam may be determined by analyzing the frequency of electron arrival events.

Electron counting may be helpful to improve signal-to-noise ratio (SNR) and throughput of a charged particle beam system. For example, a pixelated electron counting detector is made up of an array of small sensing elements, each of which can independently detect electrons at its own position. Electron counting detectors may track the spatial location or arrival time of an electron on the detector to, e.g., filter some electron arrivals as outliers or false positive detections. However, it is not necessary for an electron counting detector to retain any information of the spatial distribution of secondary electrons on a detector surface. In some comparative embodiments, spatial information such as the arrival location of a secondary electron on the detector surface may be lost after the detection is read out to a signal processing circuit. For more information about utilizing the spatial information of electron counting detectors, see for example EP22168912, which is incorporated herein by reference in its entirety. Thus, electron counting may be an attractive method in applications such as metrology and 5 overlay inspections where beam current (rate of electron flow in the beam) is usually low.

SNR may be a concern especially at low levels of primary beam current. This is because the low electron collection rate is more vulnerable to random fluctuations (shot noise) in the spatial distribution of electron arrivals on the detector. To overcome shot noise and other SNR issues, a certain minimum number of secondary electrons are collected for each sample pixel to image the pattern features with sufficient accuracy. Achieving the minimum number of secondary electron arrivals at each sample pixel imposes a certain dwell time, i.e., the more secondary electrons are required, the longer a primary beam may need to irradiate each sample pixel. Thus, the amount of time required to complete a SEM process is directly impacted by the minimum number of secondary electrons required to form an image pixel.

SNR may be an even greater concern when detecting edge features. Edge features may be detected by observing an increase in secondary electrons compared to a flat region of the sample. At low landing energies, this increase is less pronounced, and is therefore harder to distinguish from shot noise. Future SEM metrology tools may have the ability to operate with very low landing energy (kinetic energy of primary electrons when they strike the sample). For example, a very low landing energy may be required to achieve sufficient contrast in samples with thin resist layers. Landing energies of, e.g., 200 eV, 150 eV, 100 eV, 50 eV or fewer may be appropriate for such applications. This may raise the minimum number of secondary electrons needed for an accurate measurement, leading to longer dwell times and harming throughput. Achieving sufficient imaging accuracy with a lower minimum number of secondary electrons could thereby increase the speed of the entire process.

Embodiments of the present disclosure provide a system and method for reducing the minimum number of secondary electrons needed to accurately detect an edge feature in, e.g., a SEM metrology process. The system captures additional information about edge features by recording the spatial distribution of electron arrivals on, e.g. an electron counting detector or other pixelated electron detector. This additional information may be combined with conventional SEM information to detect edge features with a lower minimum number of secondary electrons than would otherwise be needed.

When a primary beam scans over a sample pixel location, a cluster (distribution) of secondary electron arrivals may be recorded at the detector surface. If the sample pixel location has an edge feature, this cluster may show an asymmetry that can help to identify the edge feature. For example, the asymmetry may be a shift of the cluster's center from where it would otherwise be, or it may be a deformation of the cluster shape. This asymmetry may then be used as the additional spatial information discussed above.

Objects and advantages of the disclosure may be realized by the elements and combinations as set forth in the embodiments discussed herein. However, embodiments of the present disclosure are not necessarily required to achieve such exemplary objects or advantages, and some embodiments may not achieve any of the stated objects or advantages.

Without limiting the scope of the present disclosure, some embodiments may be described in the context of providing detection systems and detection methods in systems utilizing electron beams (“e-beams”). However, the disclosure is not so limited. Other types of charged particle beams may be similarly applied. Furthermore, systems and methods for detection may be used in other imaging systems, such as optical imaging, photon detection, x-ray detection, ion detection, etc.

As used herein, unless specifically stated otherwise, the term “or” encompasses all possible combinations, except where infeasible. For example, if it is stated that a component includes A or B, then, unless specifically stated otherwise or infeasible, the component may include A, or B, or A and B. As a second example, if it is stated that a component includes A, B, or C, then, unless specifically stated otherwise or infeasible, the component may include A, or B, or C, or A and B, or A and C, or B and C, or A and B and C.

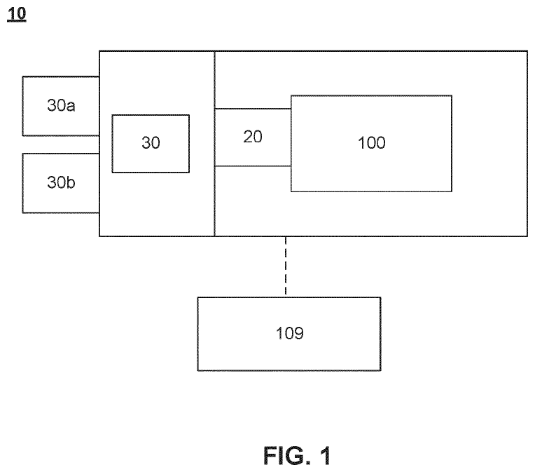

Reference is now made to FIG. 1, which illustrates an exemplary electron beam inspection (EBI) system 10 that may be used for wafer inspection, consistent with embodiments of the present disclosure. As shown in FIG. 1, EBI system 10 includes a main chamber 11 a load/lock chamber 20, an electron beam tool 100 (e.g., a scanning electron microscope (SEM)), and an equipment front end module (EFEM) 30. Electron beam tool 100 is located within main chamber 11 and may be used for imaging. EFEM 30 includes a first loading port 30a and a second loading port 30b. EFEM 30 may include additional loading ports. First loading port 30a and second loading port 30b receive wafer front opening unified pods (FOUPs) that contain wafers (e.g., semiconductor wafers or wafers made of other materials) or samples to be inspected (wafers and samples may be collectively referred to as “wafers” herein).

One or more robotic arms (not shown) in EFEM 30 may transport the wafers to load/lock chamber 20. Load/lock chamber 20 is connected to a load/lock vacuum pump system (not shown) which removes gas molecules in load/lock chamber 20 to reach a first pressure below the atmospheric pressure. After reaching the first pressure, one or more robotic arms (not shown) may transport the wafer from load/lock chamber 20 to main chamber 11. Main chamber 11 is connected to a main chamber vacuum pump system (not shown) which removes gas molecules in main chamber 11 to reach a second pressure below the first pressure. After reaching the second pressure, the wafer is subject to inspection by electron beam tool 100. Electron beam tool 100 may be a single-beam system or a multi-beam system. A controller 109 is electronically connected to electron beam tool 100, and may be electronically connected to other components as well. Controller 109 may be a computer configured to execute various controls of EBI system 10. While controller 109 is shown in FIG. 1 as being outside of the structure that includes main chamber 11, load/lock chamber 20, and EFEM 30, it is appreciated that controller 109 can be part of the structure.

A charged particle beam microscope, such as that formed by or which may be included in EBI system 10, may be capable of resolution down to, e.g., the nanometer scale, and may serve as a practical tool for inspecting IC components on wafers. With an e-beam system, electrons of a primary electron beam may be focused at probe spots on a wafer under inspection. The interactions of the primary electrons with the wafer may result in secondary particle beams being formed. The secondary particle beams may comprise backscattered electrons, secondary electrons, or Auger electrons, etc. resulting from the interactions of the primary electrons with the wafer. Characteristics of the secondary particle beams (e.g., intensity) may vary based on the properties of the internal or external structures or materials of the wafer, and thus may indicate whether the wafer includes defects.

The intensity of the secondary particle beams may be determined using a detector. The secondary particle beams may form beam spots on a surface of the detector. The detector may generate electrical signals (e.g., a current, a charge, a voltage, etc.) that represent intensity of the detected secondary particle beams. The electrical signals may be measured with measurement circuitries which may include further components (e.g., analog-to-digital converters) to obtain a distribution of the detected electrons. The electron distribution data collected during a detection time window, in combination with corresponding scan path data of the primary electron beam incident on the wafer surface, may be used to reconstruct images of the wafer structures or materials under inspection. The reconstructed images may be used to reveal various features of the internal or external structures or materials of the wafer and may be used to reveal defects that may exist in the wafer.

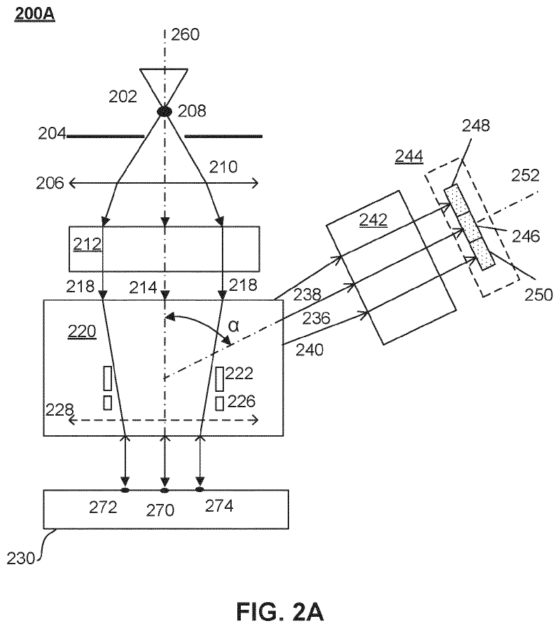

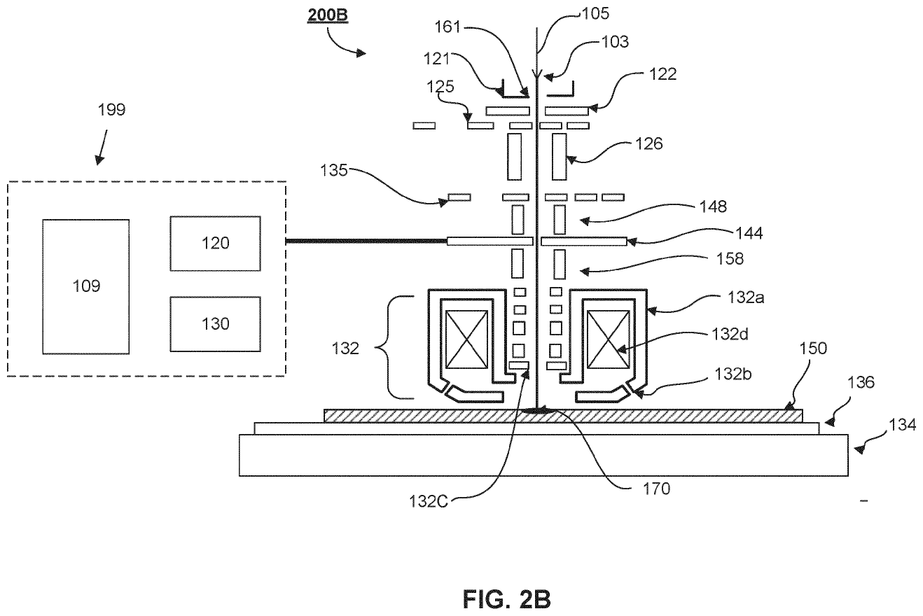

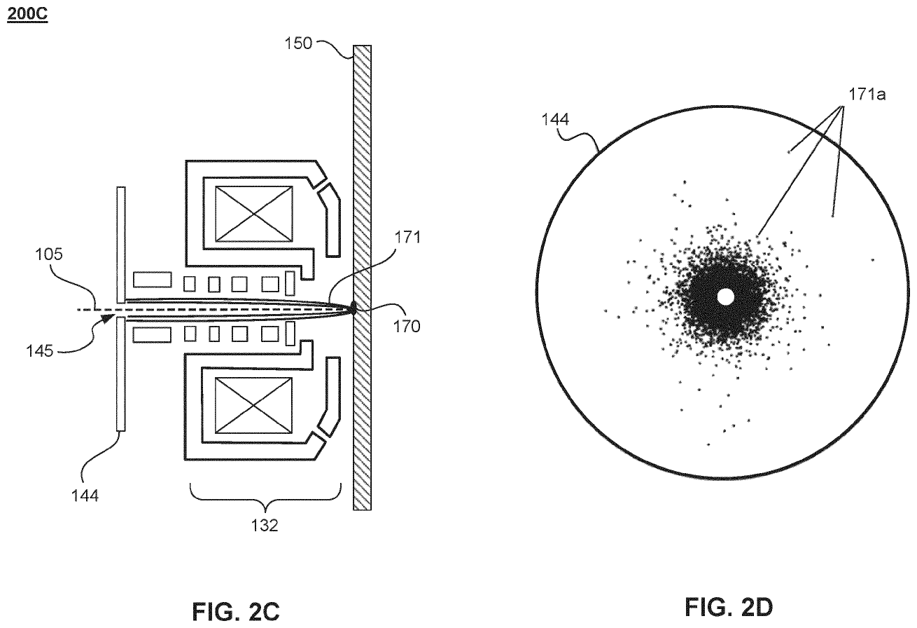

FIG. 2A illustrates an example of a charged particle beam apparatus that may be an example of electron beam tool 100, consistent with embodiments of the present disclosure. Charged particle beam apparatus 200A may be a multi-beam tool that uses a plurality of beamlets formed from a primary electron beam to simultaneously scan multiple locations on a wafer.

As shown in FIG. 2A, electron beam tool 200A may comprise an electron source 202, a gun aperture 204, a condenser lens 206, a primary electron beam 210 emitted from electron source 202, a source conversion unit 212, a plurality of beamlets 214, 216, and 218 of primary electron beam 210, a primary projection optical system 220, a wafer stage (not shown in FIG. 2A), multiple secondary electron beams 236, 238, and 240, a secondary optical system 242, and electron detection device 244. Electron source 202 may generate primary particles, such as electrons of primary electron beam 210. A controller, image processing system, and the like may be coupled to electron detection device 244. Primary projection optical system 220 may comprise beam separator 222, deflection scanning unit 226, and objective lens 228. Electron detection device 244 may comprise detection sub-regions 246, 248, and 250.

Electron source 202, gun aperture 204, condenser lens 206, source conversion unit 212, beam separator 222, deflection scanning unit 226, and objective lens 228 may be aligned with a primary optical axis 260 of apparatus 200A. Secondary optical system 242 and electron detection device 244 may be aligned with a secondary optical axis 252 of apparatus 200A.

Electron source 202 may comprise a cathode, an extractor or an anode, wherein primary electrons can be emitted from the cathode and extracted or accelerated to form a primary electron beam 210 with a crossover (virtual or real) 208. Primary electron beam 210 can be visualized as being emitted from crossover 208. Gun aperture 204 may block off peripheral electrons of primary electron beam 210 to reduce size of probe spots 270, 272, and 274.

Source conversion unit 212 may comprise an array of image-forming elements (not shown in FIG. 2A) and an array of beam-limit apertures (not shown in FIG. 2A). An example of source conversion unit 212 may be found in U.S. Pat. No. 9,691,586; U.S. Publication No. 2017/0025243; and International Publication No. WO/2018122176, all of which are incorporated by reference in their entireties. The array of image-forming elements may comprise an array of micro-deflectors or micro-lenses. The array of image-forming elements may form a plurality of parallel images (virtual or real) of crossover 208 with a plurality of beamlets 214, 216, and 218 of primary electron beam 210. The array of beam-limit apertures may limit the plurality of beamlets 214, 216, and 218.

Condenser lens 206 may focus primary electron beam 210. The electric currents of beamlets 214, 216, and 218 downstream of source conversion unit 212 may be varied by adjusting the focusing power of condenser lens 206 or by changing the radial sizes of the corresponding beam-limit apertures within the array of beam-limit apertures. Condenser lens 206 may be an adjustable condenser lens that may be configured so that the position of its first principal plane is movable. The adjustable condenser lens may be configured to be magnetic, which may result in off-axis beamlets 216 and 218 landing on the beamlet-limit apertures with rotation angles. The rotation angles change with the focusing power and the position of the first principal plane of the adjustable condenser lens. In some embodiments, the adjustable condenser lens may be an adjustable anti-rotation condenser lens, which involves an anti-rotation lens with a movable first principal plane. An example of an adjustable condenser lens is further described in U.S. Publication No. 2017/0025241, which is incorporated by reference in its entirety.

Objective lens 228 may focus beamlets 214, 216, and 218 onto a wafer 230 for inspection and may form a plurality of probe spots 270, 272, and 274 on the surface of wafer 230. Secondary electron beamlets 236, 238, and 240 may be formed that are emitted from wafer 230 and travel back toward beam separator 222.

Beam separator 222 may be a beam separator of Wien filter type generating an electrostatic dipole field and a magnetic dipole field. In some embodiments, if they are applied, the force exerted by electrostatic dipole field on an electron of beamlets 214, 216, and 218 may be equal in magnitude and opposite in direction to the force exerted on the electron by magnetic dipole field. Beamlets 214, 216, and 218 can therefore pass straight through beam separator 222 with zero deflection angle. However, the total dispersion of beamlets 214, 216, and 218 generated by beam separator 222 may also be non-zero. Beam separator 222 may separate secondary electron beams 236, 238, and 240 from beamlets 214, 216, and 218 and direct secondary electron beams 236, 238, and 240 towards secondary optical system 242.

Deflection scanning unit 226 may deflect beamlets 214, 216, and 218 to scan probe spots 270, 272, and 274 over an area on a surface of wafer 230. In response to incidence of beamlets 214, 216, and 218 at probe spots 270, 272, and 274, secondary electron beams 236, 238, and 240 may be emitted from wafer 230. Secondary electron beams 236, 238, and 240 may comprise electrons with a distribution of energies including secondary electrons and backscattered electrons. Secondary optical system 242 may focus secondary electron beams 236, 238, and 240 onto detection sub-regions 246, 248, and 250 of electron detection device 244. Detection sub-regions 246, 248, and 250 may be configured to detect corresponding secondary electron beams 236, 238, and 240 and generate corresponding signals used to reconstruct an image of the surface of wafer 230. Detection sub-regions 246, 248, and 250 may include separate detector packages, separate sensing elements, or separate regions of an array detector. In some embodiments, each detection sub-region may include a single sensing element.

FIG. 2B illustrates another example of a charged particle beam apparatus, consistent with embodiments of the present disclosure. Electron beam tool 200B (also referred to herein as apparatus 200B) may be an example of electron beam tool 100. Electron beam tool 200B may be similar to electron beam tool 200A shown in FIG. 2A. However, different from apparatus 200A, apparatus 200B may be a single-beam tool that uses one primary electron beam to scan one location on the wafer at a time.

As shown in FIG. 2B, apparatus 200B includes a wafer holder 136 supported by motorized stage 134 to hold a wafer 150 to be inspected. Electron beam tool 200B includes an electron emitter, which may comprise a cathode 103, an anode 121, and a gun aperture 122. Electron beam tool 200B further includes a beam limit aperture 125, a condenser lens 126, a column aperture 135, an objective lens assembly 132, and a detector 144. Objective lens assembly 132, in some embodiments, may be a modified SORIL lens, which includes a pole piece 132a, a control electrode 132b, a deflector 132c, and an exciting coil 132d. In a detection or imaging process, an electron beam 161 emanating from the tip of cathode 103 may be accelerated by anode 121 voltage, pass through gun aperture 122, beam limit aperture 125, condenser lens 126, and be focused into a probe spot 170 by the modified SORIL lens and impinge onto the surface of wafer 150. Probe spot 170 may be scanned across the surface of wafer 150 by a deflector, such as deflector 132c or other deflectors in the SORIL lens. Secondary or scattered particles, such as secondary electrons or scattered primary electrons emanated from the wafer surface may be collected by detector 144 to determine intensity of the beam and so that an image of an area of interest on wafer 150 may be reconstructed.

It is appreciated that electron beam tools 200A and 200B may include an image processing system 199 that includes an image acquirer 120, a storage 130, and controller 109. Image acquirer 120 may comprise one or more processors. For example, image acquirer 120 may comprise a computer, server, mainframe host, terminals, personal computer, any kind of mobile computing devices, and the like, or a combination thereof. Image acquirer 120 may connect with detector 144 of electron beam tool 200B through a medium such as an electrical conductor, optical fiber cable, portable storage media, IR, Bluetooth, internet, wireless network, wireless radio, or a combination thereof. Image acquirer 120 may receive a signal from detector 144 and may construct an image. Image acquirer 120 may thus acquire images of wafer 150. Image acquirer 120 may also perform various post-processing functions, such as image averaging, generating contours, superimposing indicators on an acquired image, and the like. Image acquirer 120 may be configured to perform adjustments of brightness and contrast, etc. of acquired images. Storage 130 may be a storage medium such as a hard disk, random access memory (RAM), cloud storage, other types of computer readable memory, and the like. Storage 130 may be coupled with image acquirer 120 and may be used for saving scanned raw image data as original images, and post-processed images. Image acquirer 120 and storage 130 may be connected to controller 109. In some embodiments, image acquirer 120, storage 130, and controller 109 may be integrated together as one electronic control unit.

In some embodiments, image acquirer 120 may acquire one or more images of a sample based on an imaging signal received from detector 144. An imaging signal may correspond to a scanning operation for conducting charged particle imaging. An acquired image may be a single image comprising a plurality of imaging areas that may contain various features of wafer 150. The single image may be stored in storage 130. Imaging may be performed on the basis of imaging frames.

The condenser and illumination optics of the electron beam tool may comprise or be supplemented by electromagnetic quadrupole electron lenses. For example, as shown in FIG. 2B, electron beam tool 200B may comprise a first quadrupole lens 148 and a second quadrupole lens 158. In some embodiments, the quadrupole lenses may be used for controlling the electron beam. For example, first quadrupole lens 148 may be controlled to adjust the beam current and second quadrupole lens 158 may be controlled to adjust the beam spot size and beam shape.

In some embodiments of the disclosure, a PIN detector may be used as an in-lens detector in a retarding objective lens SEM column of EBI system 10. The PIN detector may be placed between a cathode for generating an electron beam and the objective lens. The electron beam emitted from the cathode may be potentialized at −BE keV (typically around −10 kV). Electrons of the electron beam may be immediately accelerated and travel through the column. The column may be at ground potential.

Thus, electrons may travel with kinetic energy of BE keV while passing through opening 145 of detector 144. Electrons passing through the pole piece of the objective lens, such as pole piece 132a of objective lens assembly 132 of FIG. 2B, may be steeply decelerated down to landing energy LE keV as the wafer surface potential may be set at −(BE-LE) keV.

FIG. 2C illustrates an example of a charged particle beam apparatus 200C, consistent with embodiments of the present disclosure. Charged particle beam apparatus 200C may be, e.g., charged particle beam apparatus 200A of FIG. 2A or 200B of FIG. 2B. Emitted electrons 171, comprising e.g., secondary or backscattered electrons, are emitted from the wafer surface by the impingement of electrons of the primary electron beam 105. A retarding electric field, which may slow the primary electrons as they approach probe spot 170, may act as an acceleration electric field to accelerate the emitted electrons backwards toward a PIN detector 144 surface. For example, as shown in FIG. 2C, due to interactions with wafer 150 at probe spot 170, emitted electrons 171 may be generated that travel back toward detector 144. Emitted electrons 171 from the wafer surface travelling along optical axis 105 may arrive at the surface of detector 144 with a distribution of positions. The arrival positions of emitted electrons may be within a generally circular region with a radius of, for example, a few millimeters or more, such as 5 mm, 10 mm, or 20 mm or more. The geometric spread may increase with, e.g., increasing landing energy. A geometric spread of arrival positions of emitted electrons may be due to electrons having different trajectories that may be dependent on, for example, initial kinetic energy and emission angles of the electrons. Other factors may affect a geometric spread, or other characteristics, of arrival positions.

FIG. 2D illustrates an example of an emitted electron arrival point distribution on a detector surface. Electrons 171a may land at different points on the surface of detector 144 while, generally, most may be clustered around the central portion of detector 144 when there is no deflection field. As discussed above, emitted electrons may comprise, e.g., secondary or backscattered electrons. In some embodiments, for example, a distribution may comprise between 60-85% secondary electrons and between 40-15% backscattered electrons. The arrival point distribution may shift depending on emission position and SEM deflection fields (e.g., scan field). Therefore, in some applications, if a certain field of view (FOV) of a SEM image is required, the required size of an in-lens PIN detector may be substantially large. Typically, a detector may be 10 mm in diameter, or larger, for example. In some embodiments, a detector may be, e.g., about 4 to 10 mm in diameter.

Detector 144 may be placed along optical axis 105. The primary electron beam may be configured to travel along optical axis 105. Accordingly, detector 144 may include a hole 145 at its center so that the primary electron beam may pass through to reach wafer 150. FIGS. 2B-C show examples of a detector 144 having an opening at its center. However, some embodiments may use a detector placed off-axis relative to the optical axis along which the primary electron beam travels. For example, as in the example shown in FIG. 2A, a beam separator 222 may be provided to direct emitted electron beams toward a detector placed off-axis. Beam separator 222 may be configured to divert emitted electron beams by an angle a toward an electron detection device 244, as shown in FIG. 2A. Therefore, in some embodiments of the present disclosure, a detector may be provided that has no central opening.

Detectors 244 of FIG. 2A or 144 of FIGS. 2B-D or may include sensing elements such as diodes, or elements similar to diodes, that may convert incident energy into a measurable signal. For example, sensing elements in a detector may include a SPAD, APD, scintillator, or PIN diode. Throughout this disclosure, sensing elements may be represented as a diode, although sensing elements or other components may deviate from ideal circuit behavior of electrical elements such as diodes, resistors, capacitors, etc. In embodiments of the present disclosure, a detector in a charged particle beam system may comprise a pixelated array of multiple sensing elements. In some embodiments, the sensing elements may be configured for charged particle counting. Sensing elements of a detector that may be useful for charged particle counting are discussed in U.S. Publication No. 2019/0378682, which is incorporated by reference in its entirety.

For ease of explanation without causing ambiguity, electrons are used as examples in some of the descriptions herein. However, it should be noted that any charged particle may be used in any embodiment of this disclosure, not limited to electrons. For instance, a source in a charged-particle beam tool can emit one or more charged particles, such as electrons, protons, ions, muons, or any other particle carrying electric charges. Furthermore, some embodiments of the present disclosure may use photons instead of charged particles, such as light in the visible, UV, DUV, EUV, x-ray, or any other wavelength range. Therefore, while detectors in the present disclosure may be disclosed with respect to electron detection, some embodiments of the present disclosure may be directed to detecting other charged particles or photons.

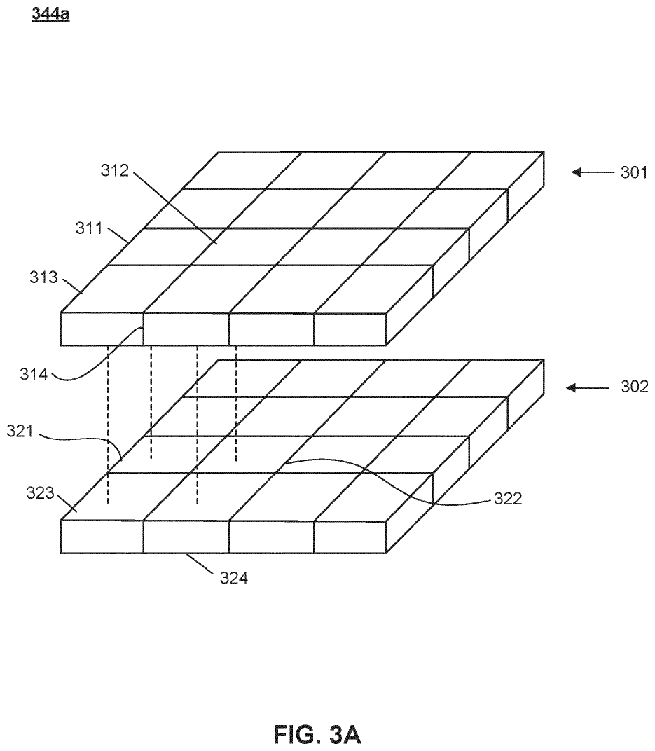

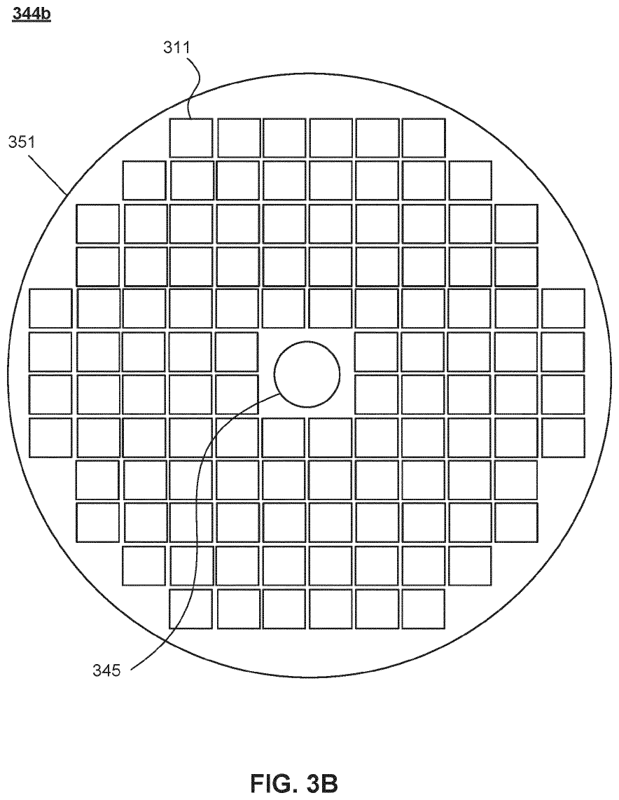

FIGS. 3A-B illustrate exemplary structures of a pixelated electron detector, consistent with embodiments of the present disclosure. A detector such as detector 344a of FIG. 3A or 344b of FIG. 3B may be provided as detector 244 as shown in FIG. 2A or 144 as shown in FIGS. 2B-D. In FIG. 3A, detector 344a includes a sensor layer 301 and a signal processing layer 302. Sensor layer 301 may include a sensor die made up of multiple sensing elements, including sensing elements 311, 312, 313, and 314. In some embodiments, the multiple sensing elements may be provided in an array of sensing elements, each of which may have a uniform size, shape, and arrangement.

Signal processing layer 302 may include multiple signal processing circuits, including circuits 321, 322, 323, and 324. The circuits may include interconnections (e.g., wiring paths) configured to communicatively couple sensing elements. Each sensing element of sensor layer 301 may have a corresponding signal processing circuit in signal processing layer 302. Sensing elements and their corresponding circuits may be configured to operate independently. As shown in FIG. 3A, circuits 321, 322, 323, and 324 may be configured to communicatively couple to outputs of sensing elements 311, 312, 313, and 314, respectively, as shown by the four dashed lines between sensor layer 301 and signal processing layer 302.

In some embodiments, signal processing layer 302 may be configured as a single die with multiple circuits provided thereon. Sensor layer 301 and signal processing layer 302 may be in direct contact. In some embodiments, components and functionality of different layers may be combined or omitted. For example, signal processing layer 302 may be combined with sensor layer 301 into a single layer. Furthermore, a circuit for charged particle counting may be integrated at various points in a detector, for example in a separate read-out layer of a detector or on a separate chip. Further details of electron counting circuitry and alternative structures for sensor layer 301 and signal processing layer 302 may be found in International Publication WO 2022/008518, the entirety of which is incorporated herein by reference.

As shown in FIG. 3B, a detector 344b having an array of sensing elements 311 may be provided. Detector 344b may be, e.g., a pixelated electron detector such as a pixelated electron counting detector. Detector 344b may include sensor layer 301 and signal processing layer 302 as seen in FIG. 3A. Detector circuitry may include an electron counting circuit separately provided for each sensing element. Detector 344b may include a plate 351, wherein the plurality of sensing elements 311 are formed thereon. Plate 351 may include opening 345 for allowing a primary electron beam to pass through plate 351.

When an individual sensing element 311 of a detector is made small compared to the geometric spread of emitted electrons incident on the detector, individual electron counting may be achieved. For example, each sensing element may have its own counting unit comprising circuitries configured to measure an output signal from the sensing element. When sensing elements are made smaller, the rate of electron arrival at each sensing element is reduced, and thus electron counting at each sensing element may become enabled. Furthermore, the capacitance of a detector may be proportional to an area of a detector surface. Some sources of noise, such as that due to components being coupled to a detector (e.g., an amplifier), may be related to capacitance. The small area of each individual element in a pixelated electron counting detector allows a much lower capacitance than, e.g., a large continuous sensing surface. For example, an individual sensing element may be a square or other shape having dimensions of, e.g. 5, 10, 25, 50, 100, 200, or 300 μm on a side. Sensing elements may be larger, e.g., on the order of millimeters. A typical detector may comprise, e.g., 100, 500, 1,000, 5,000, 10,000, 50,000 or 100,000 or more sensing elements.

Some charged particle beam processes, such as high-resolution SEM, require a very low primary beam current (e.g., down to 40 pA) and a high operation speed (e.g., 400 Mpixel per second).

Such a low primary beam current can result in a very small rate of emitted electron arrival on the detector, which in turn can increase the dwell time needed to reach a sufficient number of electrons for an accurate reading. For example, an entire detector may record only a single electron event per clock cycle (2.5 ns=1/400 MHz). Thus, a high operation speed may not be obtainable if a large number of emitted electrons are needed.

Additionally, with this low primary beam current, it can become increasingly difficult to overcome shot noise and other sources of noise. Shot noise may refer to the probabilistic nature of the spatial and temporal distribution of electron arrivals on a detector surface. Each electron landing event may occur on a detector surface with some degree of probability. In a simple situation, for example, the probability of an electron arrival occurring at a central portion of the detector may be high, with the probability decreasing with greater distance from the central portion. Additionally, the number of electrons detected during a given period also varies according to a probability function. When a large enough number of electrons is collected over a sufficient period, the random fluctuations in a spatial and temporal distribution tend to average out, and an expected distribution of electron arrival events emerges. However, when only a small number of electrons are collected, this averaging cannot take place, and an electron arrival distribution that mirrors the expected distribution is less likely. Another source of noise may be dark current, which may cause a false detection even when

there is no incident irradiation. Dark current may occur due to, e.g., defects in materials forming the detector, such as imperfections in a crystal structure of a sensing diode. The term “dark” current may refer to the fact that a current fluctuation is unrelated to incoming electrons but may nevertheless be interpreted as an arrival event. Various sources of noise, such as dark current, thermal energy, extraneous radiation, etc., may cause unintended current fluctuations in a detector's output. Dark current and the sources of noise may produce signals at locations on a detector that have a low probability of recording an actual electron arrival event.

The shot noise issue may be especially problematic when attempting to detect an edge feature in a low beam current arrangement. In comparative embodiments, the presence of an edge feature may be inferred at least in part by observing an increase in emitted electrons when the primary beam scans over an edge portion of a pattern feature. However, this increase may be less drastic at low beam currents. Therefore, it may be necessary to collect a larger number of emitted electrons to distinguish a signal from the noise. By way of example, a conventional SEM tool may require a minimum collection in the range of, e.g., 40-70, 70-100, 100-150 electrons or more for a sample pixel at an expected edge feature location. As discussed above, this higher collection rate can adversely affect the operation speed.

Embodiments of the present disclosure utilize additional information gathered during the detection process to characterize pattern features more efficiently. In particular, spatial information of electron arrivals on the detector may be used to help detect an edge feature with a smaller number of electrons than required by comparative embodiments. In some embodiments of the present disclosure, the spatial information comprises asymmetry information. The asymmetry information may comprise a measured shift in the position of a distribution of emitted electron arrivals which may be used to determine an edge feature corresponding to the measured shift. The spatial information may be combined with other information to determine the presence of an edge feature. For instance, the spatial information may be combined with an emitted electron yield map.

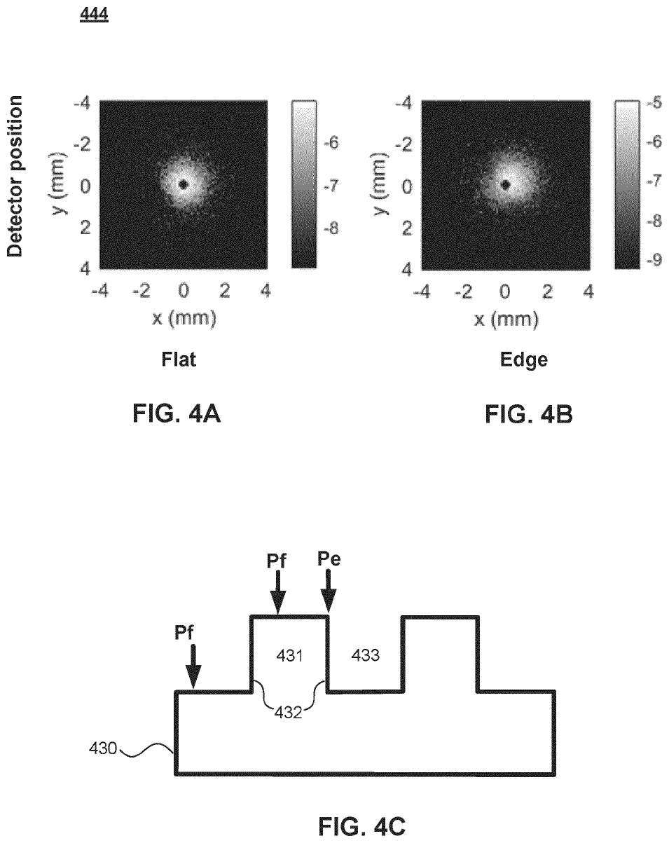

FIGS. 4A-B illustrate two simulated arrival event distributions 444 on a charged particle detector (e.g., detector 144 of FIGS. 2A-2D and 344a and 344b of FIGS. 3A-3B), consistent with embodiments of the present disclosure. The arrival events may be, e.g., emitted electron arrivals, and the charged particle detector may be an electron detector such as a pixelated electron counting detector. The scale on the right-hand side of each distribution is a grey-tone logarithmic scale of the probability of an electron arrival event at each detector pixel. White or light colored pixels indicate a higher probability of electron arrival, while darker pixels indicate a lower or zero probability. Note that in the drawings, a dark pixel at the center indicates a hole in the detector, similar to primary beam hole 345 of FIG. 3, where arrival events are not possible and probability is therefore zero. Such a hole may not be present in all embodiments of the charged particle detector, but it serves as a helpful visual reference point for the shift illustrated in FIGS. 4A-B.

FIG. 4C illustrates a cross-sectional view of pattern features 432/433 on a portion of a sample 430 undergoing a charged particle beam process, such as a SEM scan, consistent with embodiments of the present disclosure. The sample 430 may be, e.g., a semiconductor wafer having pattern features of an integrated circuit. The pattern features may comprise an alternating series of lines 431 and spaces 433 extending perpendicularly to the plane of the page. Edges 432 may be found at the interface between each line 431 and space 433. A flat region of surface topography, such as the upper surface of a line 431 or space 433, may be scanned as a flat sample pixel Pf. A transitional topography may be scanned as an edge sample pixel Pe.

FIG. 4A illustrates an arrival distribution for, e.g., one of the flat sample pixels Pf of FIG. 4C, consistent with embodiments of the present disclosure. The distribution may have a substantially symmetrical shape and be centered on the surface of detector 444. Such properties may be an indication that the sample pixel location has a substantially flat topography. The term “centered” may refer to, e.g., a centroid or geometric center of the distribution of arrival events (or probabilities of arrival events). The center may, e.g., be a weighted spatial average of arrival events or it may exclude outliers. This spatial center of arrivals may be analogized to a center of mass (COM) of a collection of point objects, and therefore may be referred to in the present application as the CoM of the emitted electron arrival distribution. In FIG. 4A, the CoM of the emitted electron arrival distribution is centered on the detector for a flat sample pixel Pf.

Note that the property of being “centered” on the detector in FIG. 4A can be affected by other known parameters of a charged particle beam process. For instance, a primary electron beam in a scanning process may be deflected two-dimensionally to scan across an entire field of view (FoV), of the sample. The primary beam may be deflected to scan in a line-by-line, zig-zag, or serpentine manner across, e.g., a rectangular FoV. The scan may form a primary beam spot at each sample pixel location within the FoV. Due to the deflection, a primary beam does not always strike a sample surface at normal incidence. This may result in a shift or deformation of the arrival distribution of emitted electrons on the detector surface. Aberrations from the lens system may also contribute to shifts and deformations. Thus, rather than having a CoM at the center of a detector surface, the arrival distribution for a flat topography may have its COM at an expected location of the detector surface after accounting for typical known parameters such as scanning deflection. Additionally, the symmetry shown in FIG. 4A may be deformed in an expected way in view of these same known parameters. Therefore, as further discussed below, a shift or deformation of the emitted electron arrival distribution may be a shift or deformation from an expected location and expected shape, respectively. For example, a deviation of a CoM for an edge sample pixel may be a deviation from the expected COM if the sample pixel had a flat topography. The shift, deformation or other spatial change from the expected parameters may be referred to as an asymmetry parameter, and it may be attributable to the presence of an edge feature in the sample pixel.

There are also fixed parameters associated with a charged particle beam system that may affect a location and distribution of electron arrival events on the detector surface, such as, e.g., electrodes, landing energy and detector height. Deflection electrodes, focusing electrodes or Wien filters may affect the location or shape of an electron distribution. Voltages on deflector electrodes can affect the divergence of the electrons as they move from the sample towards the detector. Focusing electrodes in a separate detector branch (such as 242 of FIG. 2A) may also affect location or shape. Wien filters may also be used to offset incident electrons from a detector center, e.g. to minimize loss of electron through the primary beam hole. As discussed above, a geometric spread of electron arrivals may increase with increasing landing energy as well. Additionally, an increase in detector height will result in a greater spread of electrons for a given divergence value.

FIG. 4B illustrates an emitted electron arrival distribution for a right-hand edge sample pixel Pe of FIG. 4C, consistent with embodiments of the present disclosure. An asymmetry parameter has been introduced into the distribution by the presence of an edge feature at the edge sample pixel Pe. In FIG. 4B, the CoM of the distribution is shifted away from its expected location at the detector center, and the shape of the distribution is slightly skewed toward the upper-right corner. For example, the distribution shown may correspond to an edge sample pixel Pe on the right-side edge of line 431 as shown in FIG. 4C. A distribution corresponding to a left-side edge sample pixel Pe may exhibit a similar asymmetrical shift in a different direction on the detector surface, for example in a leftward or diagonally opposite direction. Such asymmetry parameters at the detector surface may be utilized in a charged particle beam process to determine that a sample pixel comprises an edge feature.

In general, an asymmetry parameter such as a first COM deviation may shift to one side of a detector surface as a first edge feature is scanned. Next, the CoM deviation may return to a zero, or center, position as the edge is passed and a flat region is scanned. Next, as a second (opposite) edge region is scanned, a second COM deviation may appear on the detector that is shifted in a direction opposite to that of the first COM deviation. The directions of COM deviations on a detector surface may be used to gain further knowledge about a sample topography such as, e.g., to differentiate between a line and a space in the CoM map by determining whether an edge represents the beginning or end of such line/space.

The simulations depicted in FIGS. 4A-B indicate a large number of emitted electron arrivals for illustrative purposes. In some embodiments of the present disclosure, the number of emitted electron arrivals collected for a given sample pixel may be much smaller.

Additionally, a sample pixel may be the summation of one or more short electron collection periods, or frames, to yield sufficient information about the pixel. For instance, a single frame may comprise, e.g., between 0 and 100 detected electron arrival events. A summation may include, e.g., between 2 and 200 frames. In some embodiments of the present disclosure, a sample pixel may comprise, e.g., between twenty-five and several hundred or more detected electron arrival events. However, at low beam currents, the collection rates may be at the lower bound of these ranges.

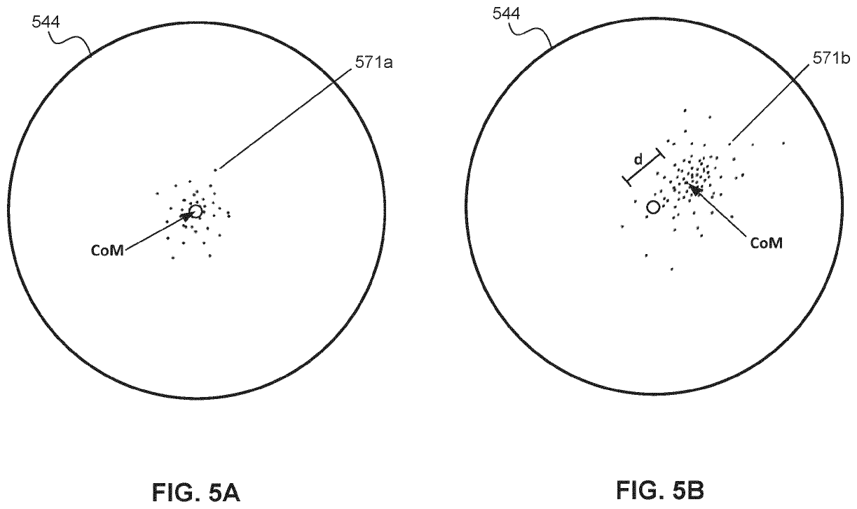

FIGS. 5A-B illustrate similar principles as those shown in FIGS. 4A-B for the surface of an example detector 544 (such as, e.g., detector 144 of FIGS. 2A-2D and 344a and 344b of FIGS. 3A-3B) in a low beam current application, consistent with embodiments of the present disclosure. In FIG. 5A, a small number of emitted electron arrivals 571a are collected on a detector surface 544 for a flat topography such as a flat sample pixel Pf of FIG. 4C. The CoM of the distribution of emitted electron arrivals 571a is substantially located at the center of detector 544, the center being indicated by a central primary beam hole. As discussed previously, this hole may not be present in some detectors. FIG. 5B illustrates a distribution of emitted electron arrivals 571b for an edge sample pixel, such as Pe in FIG. 4C. Here the COM is deviated from the detector center by a displacement d. Additionally, the shape of the distribution of emitted electron arrivals 571b is deformed with respect to the distribution shown in FIG. 5A. Finally, the number of emitted electron arrivals 571b for the edge sample pixel Pe is higher than the number of emitted electron arrivals 571a for a flat sample pixel Pf.

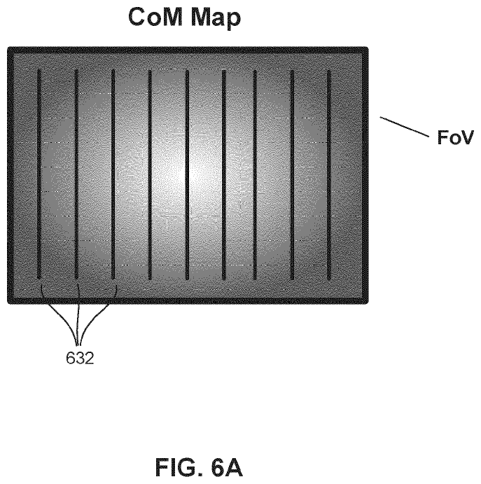

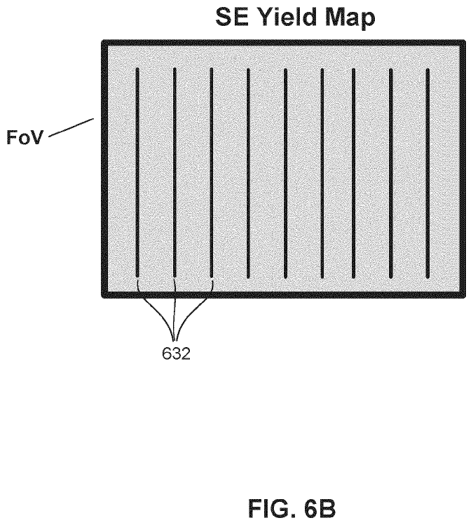

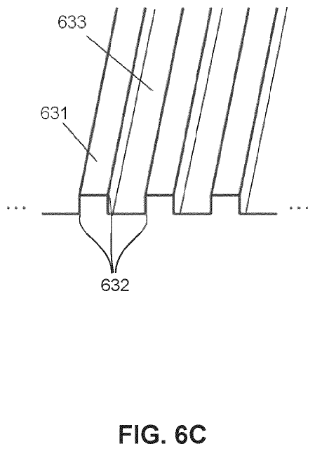

The asymmetry parameters such as COM deviation (or shape deformation) at each sample pixel in a FoV may be compiled into a CoM map as shown in FIG. 6A, where each point on the CoM map (i.e., a map pixel) corresponds to a sample pixel in the FoV. Thus, each map pixel represents an emitted electron distribution on the detector surface for one sample pixel, such as, e.g., the distributions seen in FIGS. 5A-B. Darker map pixels indicate emitted electron distributions having a larger COM deviation from a detector center (such as FIG. 5B). Lighter map pixels indicate emitted electron distributions having a smaller COM deviation from the detector center (such as FIG. 5A).

The CoM map of FIG. 6A may result from inspecting a line and space topography as shown in FIG. 6C. Here, each line in the CoM map corresponds to a vertical edge 632 at the transition between a line 631 and a space 633.

A continuous background color of the CoM map becomes gradually darker with distance from a center of the FoV. This low-spatial-frequency variation in the CoM map across the FoV may be attributable to the known parameters discussed above, such as lens aberrations and beam scanning deflections. However, the CoM map also reveals high-spatial frequency component in the form of a series of vertical lines. This COM deviation at regular intervals may be attributable to, or resulting from, edges 632 in a line and space pattern (similar to the edges 432 of FIG. 4C). The edges 632 may be identified by a controller, such as controller 109 of FIGS. 1 and 2B. For example, the controller may identify pattern edges 632 by applying a contour fitting algorithm to the CoM map in combination with predetermined information such as pattern layout data.

Instead of COM deviation, the CoM map may represent another parameter, such as a shape or other asymmetry parameter of emitted electron distributions. Alternatively, while the COM map of FIG. 6A may convey only a magnitude of deviation and not other information such as, e.g., a direction of the deviation, such additional information may be encoded on a CoM map. As one visual example, a middle gray value could represent zero deviation, while darker-than-medium pixels indicate a deviation in a first (e.g., negative) direction and lighter-than-medium pixels indicate a deviation in a second (e.g., positive) direction. The map could be, e.g., color-coded to indicate further directional or shape information. Further, the CoM map need not be embodied as a visual indicator at all. In general, the COM map may be a representation of COM parameters (such as COM deviation and shape) for a collection of sample pixels within an area (such as a FoV of a charged particle beam, system, a single die of a wafer, an entire wafer or other sample, etc).

As a further alternative to the CoM map illustrated in FIG. 6A, an aberration-corrected COM map may be derived. For instance, a CoM map may be created in which the background aberration component of FIG. 6A is subtracted from the map, or otherwise compensated or accounted for. In such a case, a CoM value may represent a deviation not from a center of the detector, but from an expected location on the detector when accounting for such aberration factors. In either case, the objective may be to determine a deviation that is attributable to an edge feature rather than to other factors.

As discussed above, spatial parameters of an electron arrival distribution are not the only indicators of an edge feature. The number of emitted electrons received on a detector surface may also increase when a primary beam spot scans an edge feature on the sample. The number of emitted electron arrivals may be recorded at each sample pixel in a FoV to produce an emitted electron yield map as shown at FIG. 6B. Here, darker map pixels on the yield map correspond to sample pixels at which a higher number of emitted electrons were collected on the detector surface (such as in FIG. 5B). Lighter map pixels on the yield map indicate that a lower number of emitted electrons were collected on the detector surface (such as in FIG. 5A).

The uniform background color of the yield map indicates a substantially constant average value for emitted electron collections at flat topographies within the FoV. However, this uniformity is shown only for illustrative purposes in comparison to the continuously varying background of FIG. 6A. In practice, a greater degree of non-uniformity in emitted electron yield may exist. Like the CoM map, the yield map reveals a series of vertical lines having a discernible increase in emitted electron yield.

These lines may correspond to the same edges 632 of the line and space pattern of FIG. 6A. A controller (e.g., controller 109) may identify edge features by applying a contour fitting algorithm to the yield map in a similar manner to the CoM map discussed above.

In a comparative embodiment, the yield map of FIG. 6B may be the primary indicator of an edge feature. For instance, in a comparative embodiment, the difference in spatial distribution between the emitted electron arrivals 571a and 571b of FIGS. 5A-B may not be recorded, and the information may be lost during signal readout. In such a case, edge features may be ascertained primarily based on differences in the number of electron arrivals acquired at each sample pixel. Because of this limited information, the minimum number of emitted electrons required to achieve a suitable contrast may be higher than what would be required when a CoM map is also available.

In some embodiments of the present disclosure, the minimum number of emitted electrons may be reduced by deriving both a CoM map and an emitted electron yield map for the same FoV. The two maps may be compared to each other or otherwise combined to yield more information about the edge features 632. For example, the two maps may be added, averaged, weighted, or scaled, etc., to yield information about edge features 632. The two maps may be combined to form a combination map. Alternatively, a first map of the two maps may be used to supplement areas of low confidence in a second map of the two maps. Using both maps may enable the edge features to be detected with a lower minimum number of emitted electrons. This lower minimum may lead to a shorter dwell time at each sample pixel, thereby increasing throughput of the charged particle beam process without sacrificing accuracy. For example, if a minimum required number of electron arrivals in a low beam current application can be reduced from, e.g., 100 to 75, it would represent a 25% increase in throughput.

In some embodiments of the present disclosure, a detector may be configured to determine not only the location of an individual electron arrival event, but also the energy of the arrival event. For example, each sensing element may be configured to generate a signal that is proportional to the energy of the electron arrival. This information may be further used to assign weighting coefficients to individual arrival events to derive an energy-weighted COM map.

Spatial information may also be utilized to determine aberrations or other system parameters, which can then be used to better analyze the results of an emitted electron yield map. In such a case, the CoM map may not be directly combined with the emitted electron yield map, but instead used to determine a system parameter to calculate a correction or adjustment to the emitted electron yield map. The opposite may also be true, that a yield map may be used to determine a correction to the CoM map.

For example, a CoM map may be used to characterize the low-spatial frequency component of COM deviation in order to monitor system drifts. The low-spatial-frequency COM variation will remain substantially consistent between multiple (similar) FoVs, as it represents a property of the system rather than the sample. System stability can thus be monitored by comparison of low-spatial-frequency COM variation over multiple scanned FoVs. The multiple FoVs may be scanned successively. Alternatively, FoVs from different regions may be compared to each other based on their expected similarity, such as due to similar pattern data or other parameters. By comparing COM information of a first FoV acquired during a first time period to COM information of a second FoV acquired during a second time period, a performance parameter of the system (e.g., lens aberrations, beam conditions, scanning conditions) can be monitored and corrected. Feed forward or feedback corrections may be applied to the system in real time based on the comparison.

Additionally, the above disclosure is made with reference to a single distribution of emitted electron arrivals for a single emitted electron beam with a singular COM deviation. However, embodiments of the present disclosure may be applicable to multi-beam configurations such as the multi-beam tool 200A of FIG. 2A. In such a case, there may be plural distributions of emitted electron arrivals on different detectors or different regions of a single detector, with each distribution having distinct COM deviations. Additionally in such a case, references to a “center” of a detector above may instead refer to a center of a detector region upon which one of the individual distributions of emitted electron arrivals is incident.

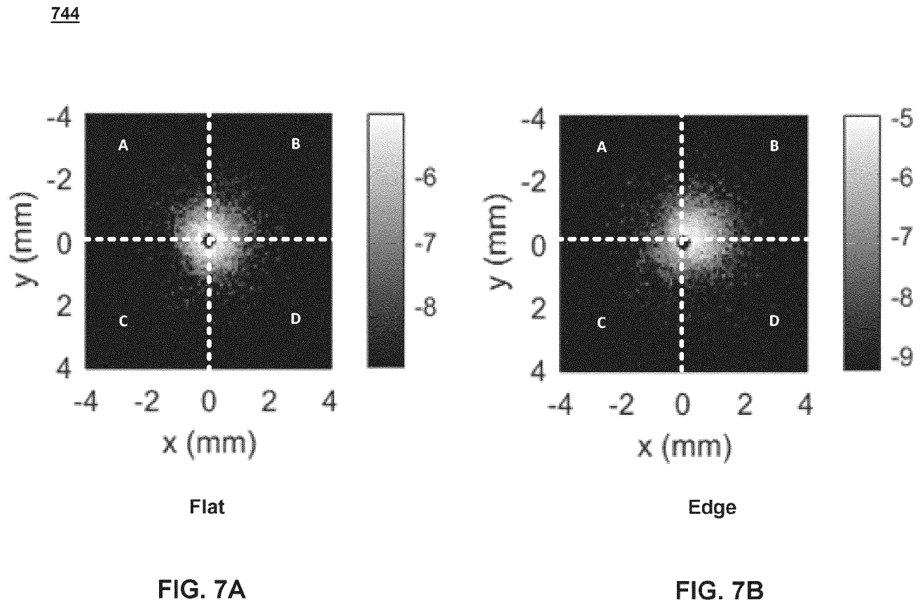

In addition to pixelated electron detectors, spatial information may be acquired using a segmented detector. For instance, a detector surface may be segmented into two halves, four quadrants, etc. By detecting a signal difference between one segment and another, a CoM deviation may be determined. FIGS. 7A-B illustrate this principle using the same distribution as those shown in FIGS. 4A-B on a segmented detector 744, consistent with embodiments of the present disclosure. Segmented detector 744 comprises four quadrants A, B, C and D. Each quadrant outputs a signal commensurate with the sum of electron arrivals that occur within that quadrant. Therefore, even though the segmented detector may not be able to differentiate individual arrival events, it is still configured to acquire enough spatial information about the electron arrivals to determine a CoM deviation by taking a difference between quadrants.

For instance, a controller could take a difference (B-C) between quadrants B and C, or a difference between two halves (B+D)−(A+C) could be measured. A difference between any or all pairs of segments could be determined. For a flat sample pixel as seen at FIG. 7A, the result of these subtractions would be low or zero due to the symmetry of electron arrivals. However, the distribution for an edge sample pixel, such as in FIG. 7B, would yield both a magnitude and direction of COM deviation. The results for each sample pixel could be compiled into COM and Yield maps as discussed above with respect to FIGS. 6A-C.

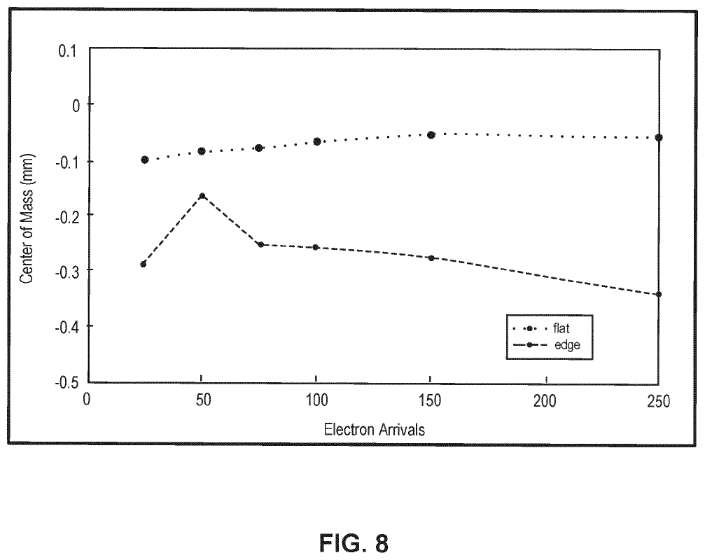

FIG. 8 schematically illustrates an experimental graph of the CoM deviation, in mm, of emitted electron arrivals on a detector, consistent with embodiments of the present disclosure. The detector may be, e.g., about 4 to 10 mm in diameter. The graph illustrates the CoM deviations for both edge and flat regions of a sample for a range of electron arrivals up to 250. The deviation shown may represent a component of the total deviation, such as a horizontal or vertical component, or it may represent the total deviation. The deviation may be from a center of the detector. Alternatively, it may represent a deviation from an expected location when considering system parameters other than topography, such as beam deflection and lens aberrations. The zero mark on the ordinate axis indicates a reference point for the CoM deviation, such as a detector center. The ordinate axis extends in the positive and negative directions from zero. However, either the positive or negative direction merely indicates the magnitude of a distance from the zero mark.

The graph of FIG. 8 shows a consistent COM difference between edge and flat regions of a sample beginning at the first data point of approximately 25 electron arrival events. At this level, the COM of emitted electron arrivals on the edge region is nearly 0.3 mm from zero, while the CoM of a flat region is offset approximately 0.1. The 50-arrival mark shows a significant difference in the COM for the edge region, which is consistent with the uncertainty that accompanies a low number of electron arrivals. However, even with this fluctuation, there is still a clear difference between edge and flat topographies. As the number of arrivals increases, the edge/flat COM values diverge from each other, confirming the relationship between topography and CoM deviation of the detector surface. But even at low numbers such as, e.g., 25 or 50 arrivals, a CoM map may be used to distinguish edge features from flat portions of a sample surface.

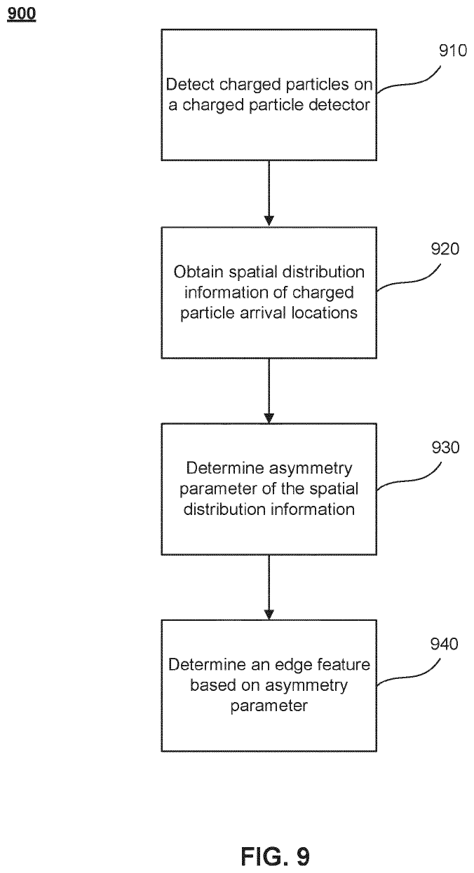

FIG. 9 illustrates a flowchart of an example method 900 of determining edge features in a sample surface using a charged particle detector, consistent with embodiments of the present disclosure. The charged particle detector may be part of a charged particle beam apparatus. For example, the charged particle beam detector may be a pixelated electron counting detector in a SEM used for scanning inspection of a sample, such as a semiconductor wafer. The method may be carried out by a processor and memory of a controller configured to control the charged particle beam apparatus to perform the method.

At step 910, a charged particle detector detects a plurality of charged particles on its surface. The detector may be, e.g., detector 244 of FIG. 2A, detector 144 of FIGS. 2B-D, detector 344a of FIG. 3A, detector 344b of FIG. 3B, or detector 544 of FIGS. 5A-B.

At step 920, the controller obtains spatial distribution information of detected charged particle arrival locations on a surface of the charged particle detector for a plurality of sample pixels in a FoV of a sample surface. For example, the spatial distribution information may comprise the arrival locations of a plurality of emitted electrons on the detector surface. The detector may be configured to individually determine the energy of each emitted electron arrival, in which case the spatial distribution information may comprise an energy-weighted distribution.

At step 930, the spatial distribution information may be used to determine an asymmetry parameter. For example, the asymmetry parameter may be a deviation of the shape of a spatial distribution of emitted electron arrival events on the detector surface. The asymmetry parameter may be a deviation of the CoM of the spatial distribution from a center the detector, or from the center of a beam spot region in a multi-beam detector. Alternatively, the asymmetry parameter may be a deviation of the CoM of the spatial distribution from an expected location on the detector when accounting for, e.g., beam deflections, lens aberrations or other system parameters. The COM may comprise a centroid or geometric center of a distribution of electron arrival events or a weighted spatial average of arrival events. The COM may comprise a centroid or geometric center of a subset of emitted electron arrivals that excludes outliers or potential false positives. The asymmetry parameter may comprise a CoM map of asymmetry parameters across a FoV of the charged particle beam apparatus. The CoM map may comprise, e.g., a CoM map as shown in FIG. 6A.

At step 940, an edge feature on the sample surface is determined based on the asymmetry parameter. For example, a contour-fitting algorithm may be applied to a CoM map, in combination with predetermined information such as pattern layout data. The edge feature may be used, e.g., in a metrology process to determine a metrology parameter. The metrology parameter may comprise, e.g., critical dimension, critical dimension uniformity, linewidth, overlay, line edge roughness, line end shortening, floor tilt, sidewall angle, and other dimensional parameters.

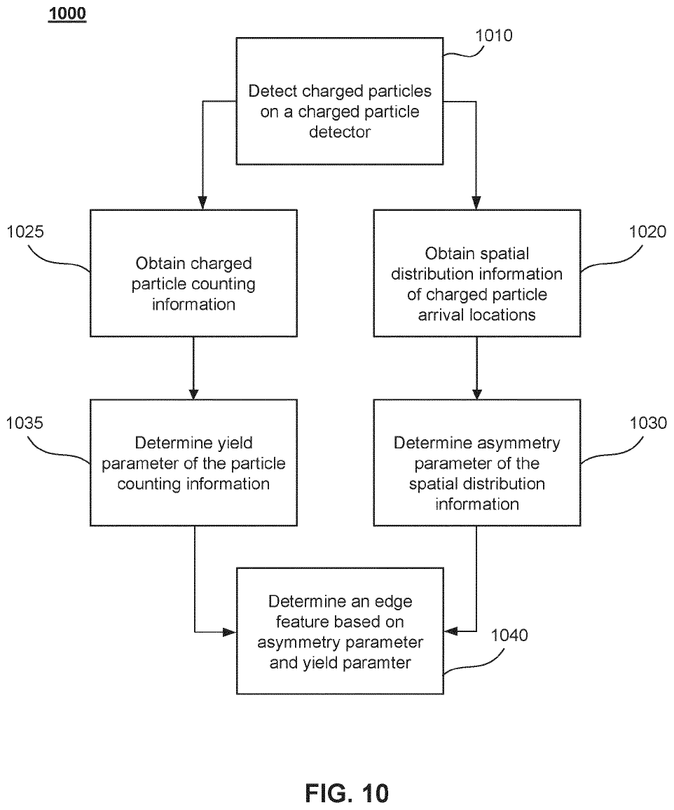

FIG. 10 illustrates a flowchart of an example method 1000 of determining edge features in a sample surface using a charged particle detector, consistent with embodiments of the present disclosure. The charged particle detector may be part of a charged particle beam apparatus. For example, the charged particle beam detector may be a pixelated electron detector such as a pixelated electron counting detector in a SEM used for scanning inspection of a sample, such as a semiconductor wafer. The method may be carried out by a processor and memory of a controller configured to control the charged particle beam apparatus to perform the method. Steps 1010-1030 may correspond to steps 910-930 of method 900 above. Step 1040 may correspond to a modified version of step 940 of method 900 above. Method 1000 further comprises the additional steps below.

At step 1025, after charged particles are detected at the detector surface at step 1010, the controller obtains charged particle counting information for a plurality of sample pixels in a FoV of a sample surface.

At step 1035, a yield parameter of the charged particle counting information is obtained. For instance, the yield parameter may be an emitted electron yield map. The emitted electron yield map may be, e.g., the yield map of FIG. 6B.

At step 1040, an edge feature on the sample surface is determined based on the yield parameter obtained at step 1035 and the asymmetry parameter obtained at step 1030. For example, contour-fitting algorithms may be applied separately to a CoM map and to an emitted electron yield map, in combination with predetermined information such as pattern layout data. The edge feature may be used, e.g., in a metrology process to determine a metrology parameter. The metrology parameter may comprise, e.g., critical dimension, critical dimension uniformity, linewidth, overlay, line edge roughness, line end shortening, floor tilt, sidewall angle, and other dimensional parameters.

A non-transitory computer-readable medium may be provided that stores instructions for a processor of a controller (e.g., controller 109 in FIG. 1) for determining edge features (such as the techniques shown above in in FIGS. 4A-9) with embodiments of the present disclosure. For example, the instructions stored in the non-transitory computer-readable medium may be executed by the circuitry of the controller for performing methods 900 or 1000 in part or in entirety. Common forms of non-transitory media include, for example, a floppy disk, a flexible disk, hard disk, solid-state drive, magnetic tape, or any other magnetic data storage medium, a Compact Disc Read-Only Memory (CD-ROM), any other optical data storage medium, any physical medium with patterns of holes, a Random Access Memory (RAM), a Programmable Read-Only Memory (PROM), and Erasable Programmable Read-Only Memory (EPROM), a FLASH-EPROM or any other flash memory, Non-Volatile Random Access Memory (NVRAM), a cache, a register, any other memory chip or cartridge, and networked versions of the same.

The embodiments may further be described using the following clauses:
1. A non-transitory computer-readable medium storing a set of instructions that are executable by at least one processor of a device to cause the device to perform a method comprising:
   inspecting a sample surface using a charged particle beam system;
   obtaining spatial distribution information of locations of detected charged particle arrivals on a charged particle detector;
   determining an asymmetry parameter of the spatial distribution information; and
   determining an edge feature on the sample surface based on the asymmetry parameter.
2. The non-transitory computer-readable medium of clause 1, wherein the asymmetry parameter comprises a position parameter of the locations of detected charged particle arrivals on the charged particle detector.
3. The non-transitory computer-readable medium of clause 2, wherein the position parameter comprises a deviation of a center of mass (COM) of the locations of detected charged particle arrivals, the deviation resulting from the edge feature.
4. The non-transitory computer-readable medium of clause 1, wherein the asymmetry parameter comprises a shape parameter of the locations of detected charged particle arrivals on the charged particle detector.
5. The non-transitory computer-readable medium of clause 4, wherein the shape parameter comprises a deviation of a shape of the locations of detected charged particle arrivals on the charged particle detector, said deviation resulting from the edge feature.
6. The non-transitory computer-readable medium of clause 1, wherein the set of instructions that are executable by the at least one processor is configured to cause the device to further perform:
   determining a CoM map based on the asymmetry parameter of the locations of detected charged particle arrivals;
   wherein determining the edge feature is based on the CoM map.
7. The non-transitory computer-readable medium of clause 1, wherein the set of instructions that are executable by the at least one processor is configured to cause the device to further perform: obtaining yield information of the detected charged particle arrivals;
   determining a yield parameter of the detected charged particle arrivals based on the yield information; wherein determining the edge feature is based on both the yield parameter and the asymmetry parameter.
8. The non-transitory computer-readable medium of clause 7, wherein the yield parameter comprises a charged particle yield map.
9. The non-transitory computer-readable medium of clause 7, wherein the asymmetry parameter comprises a CoM map.
10. The non-transitory computer-readable medium of clause 1, wherein the spatial distribution information comprises fewer than 120 locations of detected charged particle arrivals.
11. The non-transitory computer-readable medium of clause 10, wherein the spatial distribution information comprises fewer than 50 locations of detected charged particle arrivals.
12. The non-transitory computer-readable medium of clause 1, wherein the charged particle detector is an electron detector.
13. The non-transitory computer-readable medium of clause 12, wherein the electron detector is one of a four-quadrant segmented detector, a two-half segmented detector, and a pixelated electron counting detector.
14. The non-transitory computer-readable medium of clause 1, wherein the charged particle beam apparatus comprises a scanning electron microscope.
15. A method of determining an edge feature on a sample surface, comprising: inspecting the sample surface using a charged particle beam system;
   obtaining spatial distribution information of locations of detected charged particle arrivals on a charged particle detector;
   determining an asymmetry parameter of the spatial distribution information; and determining an edge feature on the sample surface based on the asymmetry parameter.
16. The method of clause 15, wherein the asymmetry parameter comprises a position parameter of the locations of detected charged particle arrivals on the charged particle detector.
17. The method of clause 16, wherein the position parameter comprises a deviation of a CoM of the locations of detected charged particle arrivals, said deviation resulting from the edge feature.
18. The method of clause 15, wherein the asymmetry parameter comprises a shape parameter of the locations of detected charged particle arrivals on the charged particle detector.
19. The method of clause 18, wherein the shape parameter comprises a deviation of a shape of the locations of detected charged particle arrivals on the charged particle detector, said deviation resulting from the edge feature.
20. The method of clause 15, further comprising:
   determining a CoM map based on the asymmetry parameter of the locations of detected charged particle arrivals;
   wherein determining the edge feature is based on the CoM map.
21. The method of clause 15, further comprising:
   obtaining yield information of the detected charged particle arrivals;
   determining a yield parameter of the detected charged particle arrivals;
   wherein determining the edge feature is based on both the yield parameter and the asymmetry parameter.
22. The method of clause 21, wherein the yield parameter comprises a charged particle yield map.
23. The method of clause 21, wherein the asymmetry parameter comprises a CoM map.
24. The method of clause 15, wherein the spatial distribution information comprises fewer than 120 locations of detected charged particle arrivals.
25. The method of clause 24, wherein the spatial distribution information comprises fewer than 50 locations of detected charged particle arrivals.
26. The method of clause 15, wherein the charged particle detector is one of an electron detector or a proton detector.
27. The method of clause 26, wherein the electron detector is one of a four-quadrant segmented detector, a two-half segmented detector, and a pixelated electron counting detector.
28. The method of clause 15, wherein the charged particle beam apparatus comprises a scanning electron microscope.
29. A charged particle beam apparatus, comprising:
   a charged particle beam source configured to generate a beam of primary charged particles;
   an optical system configured to direct the beam of primary charged particles at a sample surface to inspect the sample surface;
   a charged particle detector configured to detect a spatial distribution of detected charged particles returned from the sample surface;
   a controller comprising one or more processors and configured to cause the charged particle beam apparatus to perform:
   obtain spatial distribution information of locations of detected charged particle arrivals on the charged particle detector;
   determine an asymmetry parameter of the spatial distribution information; and
   determine an edge feature on the sample surface based on the asymmetry parameter.
30. The charged particle beam apparatus of clause 29, wherein the asymmetry parameter comprises a position parameter of the locations of detected charged particle arrivals on the charged particle detector.
31. The charged particle beam apparatus of clause 30, wherein the position parameter comprises a deviation of a CoM of the locations of detected charged particle arrivals, said deviation resulting from the edge feature.
32. The charged particle beam apparatus of clause 29, wherein the asymmetry parameter comprises a shape parameter of the locations of detected charged particle arrivals on the charged particle detector.
33. The charged particle beam apparatus of clause 32, wherein the shape parameter comprises a deviation of a shape of the locations of detected charged particle arrivals on the charged particle detector, said deviation resulting from the edge feature.
34. The charged particle beam apparatus of clause 29, wherein the controller is further configured to
   cause the charged particle beam apparatus to perform:
   determine a CoM map based on the asymmetry parameter of the locations of detected charged particle arrivals;
   wherein determining the edge feature is based on the CoM map.

35. The charged particle beam apparatus of clause 29, wherein the controller is further configured to cause the charged particle beam apparatus to perform:

obtaining yield information of the detected charged particle arrivals;
determining a yield parameter of the detected charged particle arrivals;
wherein determining the edge feature is based on both the yield parameter and the asymmetry parameter.
36. The charged particle beam apparatus of clause 35, wherein the yield parameter comprises a charged particle yield map.
37. The charged particle beam apparatus of clause 35, wherein the asymmetry parameter comprises a CoM map.
38. The charged particle beam apparatus of clause 29, wherein the spatial distribution information comprises fewer than 120 locations of detected charged particle arrivals.
39. The charged particle beam apparatus of clause 38, wherein the spatial distribution information comprises fewer than 50 locations of detected charged particle arrivals.
40. The charged particle beam apparatus of clause 29, wherein the charged particle detector is one of an electron detector or a proton detector.
41. The charged particle beam apparatus of clause 40, wherein the electron detector is one of a four-quadrant segmented detector, a two-half segmented detector, and a pixelated electron counting detector.
42. The charged particle beam apparatus of clause 29, wherein the charged particle beam apparatus comprises a scanning electron microscope.
43. A non-transitory computer-readable medium storing a set of instructions that are executable by
   at least one processor of a device to cause the device to perform a method comprising:
   inspecting a sample surface using a charged particle beam system;
   obtaining first spatial distribution information of locations of detected charged particle arrivals on a charged particle detector in a first time period;
   obtaining second spatial distribution information of locations of detected charged particle arrivals on the charged particle detector in a second time period different from the first time period;
   determining a performance parameter of the charged particle beam system based on the first spatial distribution information and the second spatial distribution information; and
   performing an adjustment to the charged particle system based on the determined performance parameter.

44. A charged particle beam method, comprising:

inspecting the sample surface using a charged particle beam system; obtaining first spatial distribution information of locations of detected charged particle arrivals on a charged particle detector in a first time period;
obtaining second spatial distribution information of locations of detected charged particle arrivals on the charged particle detector in a second time period different from the first time period;
determining a performance parameter of the charged particle beam system based on the first spatial distribution information and the second spatial distribution information; and performing an adjustment to the charged particle system based on the determined performance parameter.
45. A charged particle beam apparatus, comprising:
   a charged particle beam source configured to generate a beam of primary charged particles;
   an optical system configured to direct the beam of primary charged particles at a sample surface to inspect the sample surface;
   a charged particle detector configured to detect a spatial distribution of detected charged particles returned from the sample surface;
   a controller comprising one or more processors and configured to cause the charged particle beam apparatus to perform:
   obtaining first spatial distribution information of locations of detected charged particle arrivals on a charged particle detector in a first time period;
   obtaining second spatial distribution information of locations of detected charged particle arrivals on the charged particle detector in a second time period different from the first time period;
   determining a performance parameter of the charged particle beam system based on the first spatial distribution information and the second spatial distribution information; and
   performing an adjustment to the charged particle system based on the determined performance parameter.
46. A non-transitory computer-readable medium storing a set of instructions that are executable by at least one processor of a device to cause the device to perform a method comprising:
   inspecting a sample surface using a charged particle beam system;
   detecting a plurality of sample pixels within a field of view of the sample, wherein detecting each sample pixel of the plurality of sample pixels comprises detecting a plurality of charged particles emitted from the sample pixel; and
   determining a map of center of mass deviations of each plurality of charged particles emitted from each sample pixel of the plurality of sample pixels.
47. A charged particle beam method, comprising:
   inspecting the sample surface using a charged particle beam system;
   detecting a plurality of sample pixels within a field of view of the sample, wherein detecting each sample pixel of the plurality of sample pixels comprises detecting a plurality of charged particles emitted from the sample pixel; and
   determining a map of center of mass deviations of each plurality of charged particles emitted from each sample pixel of the plurality of sample pixels.
48. A charged particle beam apparatus, comprising:
   a charged particle beam source configured to generate a beam of primary charged particles;
   an optical system configured to direct the beam of primary charged particles at a sample surface to inspect the sample surface;
   a charged particle detector configured to detect charged particles returned from the sample surface; a controller comprising one or more processors and configured to cause the charged particle beam apparatus to perform:
   detecting a plurality of sample pixels within a field of view of the sample, wherein detecting each sample pixel of the plurality of sample pixels comprises detecting a plurality of charged particles emitted from the sample pixel; and
   determining a map of center of mass deviations of each plurality of charged particles emitted from each sample pixel of the plurality of sample pixels.

Some embodiments of the present disclosure have been described with respect to electron beam systems, such as SEM, having an electron detector for detecting electron arrivals. However, the present disclosure is not limited to this. It should be understood that the above disclosed embodiments may be applicable to other systems, such as other non-SEM electron beam systems or non-electron based charged particle beam systems. Further, it should be understood that other charged particles, or other classes of electrons are contemplated within the scope of the present disclosure.

Block diagrams in the figures may illustrate the architecture, functionality, and operation of possible implementations of systems, methods, and computer hardware or software products according to various exemplary embodiments of the present disclosure. In this regard, each block in a schematic diagram may represent certain arithmetical or logical operation processing that may be implemented using hardware such as an electronic circuit. Blocks may also represent a module, segment, or portion of code that comprises one or more executable instructions for implementing the specified logical functions. It should be understood that in some alternative implementations, functions indicated in a block may occur out of the order noted in the figures. For example, two blocks shown in succession may be executed or implemented substantially concurrently, or two blocks may sometimes be executed in reverse order, depending upon the functionality involved. Some blocks may also be omitted. It should also be understood that each block of the block diagrams, and combination of the blocks, may be implemented by special purpose hardware-based systems that perform the specified functions or acts, or by combinations of special purpose hardware and computer instructions.

It will be appreciated that the embodiments of the present disclosure are not limited to the exact construction that has been described above and illustrated in the accompanying drawings, and that various modifications and changes can be made without departing from the scope thereof. For example, a charged particle inspection system may be but one example of a charged particle beam system consistent with embodiments of the present disclosure.

1. A non-transitory computer-readable medium storing a set of instructions that are executable by at least one processor of a device to cause the device to perform a method comprising:
inspecting a sample surface using a charged particle beam system;
obtaining spatial distribution information of locations of detected charged particle arrivals on a charged particle detector;
determining an asymmetry parameter of the spatial distribution information; and
determining an edge feature on the sample surface based on the asymmetry parameter.

2. The non-transitory computer-readable medium of claim 1, wherein the asymmetry parameter comprises a position parameter of the locations of detected charged particle arrivals on the charged particle detector.

3. The non-transitory computer-readable medium of claim 2, wherein the position parameter comprises a deviation of a center of mass (COM) of the locations of detected charged particle arrivals, the deviation resulting from the edge feature.

4. The non-transitory computer-readable medium of claim 1, wherein the asymmetry parameter comprises a shape parameter of the locations of detected charged particle arrivals on the charged particle detector.

5. The non-transitory computer-readable medium of claim 4, wherein the shape parameter comprises a deviation of a shape of the locations of detected charged particle arrivals on the charged particle detector, said deviation resulting from the edge feature.

6. The non-transitory computer-readable medium of claim 1, wherein the set of instructions that are executable by the at least one processor is configured to cause the device to further perform:
determining a CoM map based on the asymmetry parameter of the locations of detected charged particle arrivals;
wherein determining the edge feature is based on the CoM map.

7. The non-transitory computer-readable medium of claim 1, wherein the set of instructions that are executable by the at least one processor is configured to cause the device to further perform:
obtaining yield information of the detected charged particle arrivals;
determining a yield parameter of the detected charged particle arrivals based on the yield information;
wherein determining the edge feature is based on both the yield parameter and the asymmetry parameter.

8. The non-transitory computer-readable medium of claim 7, wherein the yield parameter comprises a charged particle yield map.

9. The non-transitory computer-readable medium of claim 7, wherein the asymmetry parameter comprises a CoM map.

10. The non-transitory computer-readable medium of claim 1, wherein the spatial distribution information comprises fewer than 120 locations of detected charged particle arrivals.

11. The non-transitory computer-readable medium of claim 10, wherein the spatial distribution information comprises fewer than 50 locations of detected charged particle arrivals.

12. The non-transitory computer-readable medium of claim 1, wherein the charged particle detector is an electron detector.

13. The non-transitory computer-readable medium of claim 12, wherein the electron detector is one of a four-quadrant segmented detector, a two-half segmented detector, and a pixelated electron counting detector.

14. The non-transitory computer-readable medium of claim 1, wherein the charged particle beam appratus system comprises a scanning electron microscope.

15. A method of determining an edge feature on a sample surface, comprising:
inspecting the sample surface using a charged particle beam system;
obtaining spatial distribution information of locations of detected charged particle arrivals on a charged particle detector;
determining an asymmetry parameter of the spatial distribution information; and
determining an edge feature on the sample surface based on the asymmetry parameter.

16. A charged particle beam apparatus, comprising:
a charged particle beam source configured to generate a beam of primary charged particles;
an optical system configured to direct the beam of primary charged particles at a sample surface to inspect the sample surface;
a charged particle detector configured to detect a spatial distribution of detected charged particles returned from the sample surface;
a controller comprising one or more processors and configured to cause the charged particle beam apparatus to perform:
obtain spatial distribution information of locations of detected charged particle arrivals on the charged particle detector;
determine an asymmetry parameter of the spatial distribution information; and
determine an edge feature on the sample surface based on the asymmetry parameter.

17. The charged particle beam apparatus of claim 16, wherein the asymmetry parameter comprises a position parameter of the locations of detected charged particle arrivals on the charged particle detector.

18. The charged particle beam apparatus of claim 17, wherein the position parameter comprises a deviation of a CoM of the locations of detected charged particle arrivals, said deviation resulting from the edge feature.

19. The charged particle beam apparatus of claim 16, wherein the asymmetry parameter comprises a shape parameter of the locations of detected charged particle arrivals on the charged particle detector.

20. The charged particle beam apparatus of claim 19, wherein the shape parameter comprises a deviation of a shape of the locations of detected charged particle arrivals on the charged particle detector, said deviation resulting from the edge feature.
